(19) United States
(12) Patent Application Publication
(10) Pub. No.: US 2026/0343903 A1
(43) Pub. Date: Oct. 29, 2026

(54) SEMICONDUCTOR DEVICE AND SEMICONDUCTOR PACKAGE INCLUDING THE SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/299,217

(22) Filed: Aug. 13, 2025

(30) Foreign Application Priority Data
Apr. 23, 2025 (KR) 10-2025-0052769

(51) Int. Cl. H10B 80/00; H10D 80/30; H10W 70/60; H10W 74/10; H10W 90/00; H10W 20/20; H10W 72/00; H10W 72/50; H10W 90/20; H10W 90/24

(52) U.S. Cl. CPC H10B 80/00; H10D 80/30; H10W 70/611; H10W 74/121; H10W 90/00; H10W 90/401; H10W 20/20; H10W 72/075; H10W 72/07553; H10W 72/531; H10W 90/24; H10W 90/297; H10W 90/754; H10W 90/792

(57) ABSTRACT

A semiconductor package includes a first semiconductor device and a second semiconductor device stacked thereon. The first device comprises a first semiconductor chip including a substrate, a circuit layer beneath the substrate, a wiring layer beneath the circuit layer, and a through-electrode penetrating the substrate and circuit layer to connect to a bonding pad. A bonding wire is connected to the bonding pad, and a mold layer covers the chip and surrounds the bonding wire. A redistribution layer is over the mold layer and the bonding wire, with connecting members thereon. The second device comprises a second semiconductor chip including a substrate, a circuit layer thereon, a wiring layer on the circuit layer, and a through-electrode connecting to a bonding pad under the substrate. A bonding wire, mold layer, and redistribution layer are provided, with connecting members bonded to those of the first device.

### CROSS-REFERENCE TO RELATED APPLICATIONS

The present application claims priority under 35 U.S.C. 119(a) to Korean patent application number 10-2025-0052769 filed on Apri.23, 2025, which is incorporated herein by reference in its entirety.

### TECHNICAL FIELD

Embodiments of the present disclosure relate to semiconductor technology, and more specifically, to a semiconductor device including a semiconductor chip and a semiconductor package including the semiconductor device.

### BACKGROUND

Electronic devices are becoming smaller in size while requiring high-capacity data processing. Accordingly, there is a growing need to increase the integration of semiconductor devices used in electronic products. Because it is difficult to satisfy the required functions with only a single semiconductor chip due to the limitations of integration technology, semiconductor packages are being manufactured using multiple semiconductor chips.

Even if a semiconductor package includes multiple semiconductor chips, it is required to be made to a specified thickness or thinner depending on the requirements of the application in which the semiconductor package is mounted.

Making a semiconductor chip thinner can reduce a thickness of a semiconductor package, but the decrease in thickness may cause a warpage in the semiconductor chip, and defects such as chip cracks and chipping may occur.

### SUMMARY

Embodiments of the disclosure may provide a semiconductor device and a semiconductor package including the semiconductor device.

The objects of embodiments of the present disclosure are not limited to the objects described in this specification, and other objects will be clearly understood by those skilled in the art from the description below.

A semiconductor package according to an embodiment of the present disclosure may include a first semiconductor device; and a second semiconductor device stacked on the first semiconductor device. The first semiconductor device includes: a first semiconductor chip including a first substrate, a first circuit layer disposed under the first substrate, a first wiring layer disposed under the first circuit layer, a first through-electrode vertically penetrating the first substrate and the first circuit layer, and a first bonding pad disposed on the first substrate and connected to the first through-electrode; a first bonding wire connected to the first bonding pad; a first mold layer disposed to cover the first semiconductor chip and surround the first bonding wire; a first redistribution layer disposed on the first mold layer and the first bonding wire; and first connecting members disposed on the first redistribution layer. The second semiconductor device includes: a second semiconductor chip including a second substrate, a second circuit layer disposed on the second substrate, a second wiring layer disposed on the second circuit layer, a second through- electrode vertically penetrating the second substrate and the second circuit layer, and a second bonding pad disposed under the second substrate and connected to the second through-electrode; a second bonding wire connected to the second bonding pad; a second mold layer disposed to cover the second semiconductor chip and surround the second bonding wire; a second redistribution layer disposed under the second mold layer and the second bonding wire; and second connecting members disposed under the second redistribution layer and bonded to the first connecting members.

A semiconductor device according to an embodiment of the present disclosure may include a first semiconductor chip including a first substrate, a first circuit layer disposed under the first substrate, a first wiring layer disposed under the first circuit layer, a first through-electrode vertically penetrating the first substrate and the first circuit layer, and a first bonding pad disposed on the first substrate and connected to the first through-electrode; a second semiconductor chip disposed on the first semiconductor chip, the second semiconductor chip including a second substrate, a second circuit layer disposed under the second substrate, a second wiring layer disposed under the second circuit layer, a second through-electrode vertically penetrating the second substrate and the second circuit layer, and a second bonding pad disposed on the second substrate and connected to the second through-electrode; a first bonding wire connected to the first bonding pad; a second bonding wire connected to the second bonding pad; a mold layer disposed to cover the first semiconductor chip and the second semiconductor chip and surround the first bonding wire and the second bonding wire; a redistribution layer disposed on the mold layer and the first bonding wire and the second bonding wire; and connecting members disposed on the redistribution layer.

A semiconductor package according to an embodiment of the present disclosure may include a base chip; a first semiconductor device stacked on the base chip; a second semiconductor device stacked on the first semiconductor device; and an outer mold layer disposed on the base chip to seal the first semiconductor device and the second semiconductor device. The first semiconductor device includes: a first semiconductor chip including a first substrate, a first circuit layer disposed under the first substrate, a first wiring layer disposed under the first circuit layer, and a first through-electrode vertically penetrating the first substrate and the first circuit layer; a first bonding wire connected to the first through-electrode; a first mold layer disposed to cover the first semiconductor chip and surround the first bonding wire; a first redistribution layer disposed on the first mold layer and the first bonding wire; and first connecting members disposed on the first redistribution layer The second semiconductor device includes: a second semiconductor chip including a second substrate, a second circuit layer disposed on the second substrate, a second wiring layer disposed on the second circuit layer, and a second through-electrode vertically penetrating the second substrate and the second circuit layer; a second bonding wire connected to the second through-electrode; a second mold layer covering the second semiconductor chip and surrounding the second bonding wire; a second redistribution layer disposed under the second mold layer and the second bonding wire; and second connecting members disposed under the second redistribution layer and bonded to the first connecting members. Third connecting members disposed under the first through-electrode and fourth connecting members disposed on the base chip may be bonded to each other.

According to embodiments of the present disclosure, it is possible to provide a semiconductor device and a semiconductor package having the semiconductor device.

The effects of embodiments of the present disclosure are not limited to the effects described in this specification, and other effects will be clearly understood by those skilled in the art from the description of the claims.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 is a cross-sectional view of a semiconductor package according to an embodiment of the present disclosure.

FIG. 2 is a cross-sectional view of a semiconductor device according to an embodiment of the present disclosure.

FIG. 3 is a cross-sectional view of a semiconductor package according to another embodiment of the present disclosure.

FIG. 4 is a cross-sectional view of a semiconductor package according to further another embodiment of the present disclosure.

FIG. 5 is a cross-sectional view along line I-I` of the semiconductor package of FIG. 3.

FIG. 6 is a flowchart for describing a method for manufacturing a semiconductor device according to one embodiment of the present disclosure.

FIGS. 7-14 are cross-sectional views illustrating a semiconductor device in a process sequence, according to an embodiment of the present disclosure.

### DETAIL DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements, but is used merely to distinguish the corresponding element from other elements.

In the description of the positional relationship of elements, if two or more elements are described as being "connected", "combined" or "connected", it should be understood that the two or more elements may be directly "connected", "combined" or "connected", but the two or more elements and the other element may be further "interposed" to be "connected", "combined" or "connected". Here, the other elements may be included in one or more of the two or more elements that are "connected", "combined" or "connected" to each other.

In the description of the temporal flow relationship related to elements, or the method of operation or manufacturing method, for example, if the temporal chronological relationship or the chronological flow relationship is described as "after", "following", "next to", or "before", it may also include cases where it is not continuous, unless "right away" or "directly" is used.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”

Hereinafter, various embodiments of the present disclosure will be described in detail with reference to accompanying drawings.

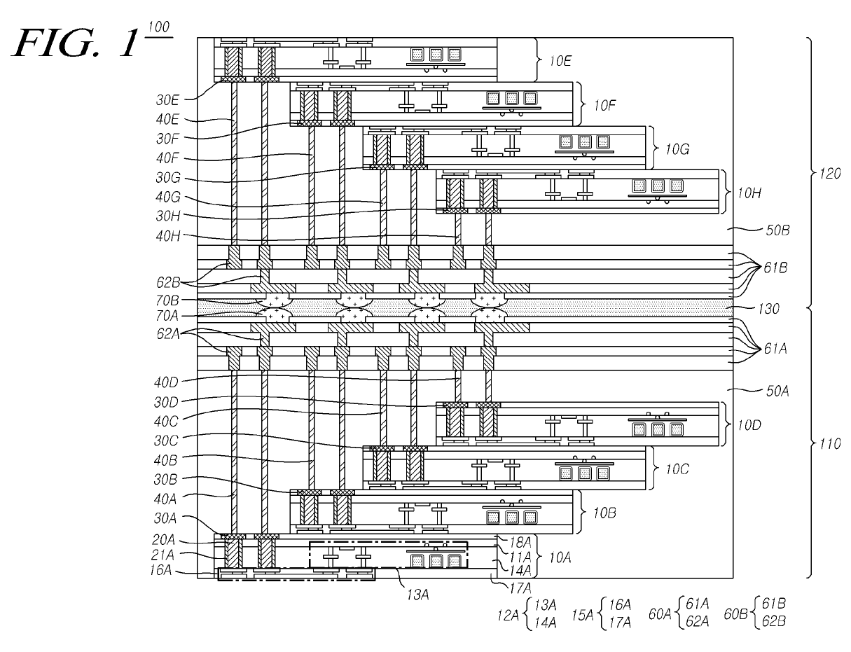

FIG. 1 is a cross-sectional view of a semiconductor package according to an embodiment of the present disclosure.

Referring to FIG. 1, a semiconductor package 100 according to an embodiment of the present disclosure may include a first semiconductor device 110 and a second semiconductor device 120 bonded to the first semiconductor device 110. In addition, the semiconductor package 100 according to an embodiment of the present disclosure may further include a center mold layer 130.

The first semiconductor device 110 may include a first semiconductor chip to a fourth semiconductor chip 10A, 10B, 10C, and 10D, a first bonding wire to a fourth bonding wire 40A, 40B, 40C, and 40D, a first mold layer 50A, a first redistribution layer 60A, and first connecting members 70A.

The first semiconductor chip 10A may include a first substrate 11A, a first circuit layer 12A, a first wiring layer 15A, a first through-electrode 20A, and a first bonding pad 30A.

The first substrate 11A may be a silicon substrate, a silicon germanium (SiGe) substrate, a gallium arsenide (GaAs) substrate, a germanium (Ge) substrate, or a SOI (Silion-On-Insulator) substrate.

The first circuit layer 12A may be disposed on a lower surface of the first substrate 11A.

The first circuit layer 12A may include a first integrated circuit 13A and a first insulating layer 14A.

The first integrated circuit 13A may include a memory cell. The memory cell may be a DRAM cell, but the type of the memory cell is not limited thereto.

The first through-electrode 20A may vertically penetrate the first substrate 11A and the first circuit layer 12A.

The first circuit layer 12A may include an upper surface in contact with the first substrate 11A and a lower surface opposite to the upper surface. One end of the first through-electrode 20A may be exposed to the lower surface of the first circuit layer 12A, and the other end of the first through-electrode 20A opposite to the one end may be exposed to the upper surface of the first substrate 11A.

The first wiring layer 15A may be disposed under the lower surface of the first circuit layer 12A. The first wiring layer 15A may include first wiring patterns 16A, a second insulating layer 17A, and a first chip pad (not shown). The first chip pad (not shown) may be disposed on the lower surface of the first wiring layer 15A.

The first through-electrode 20A may be electrically connected to the first integrated circuit 13A through the first wiring patterns 16A of the first wiring layer 15A. The first semiconductor chip 10A may be disposed in a face-down form with the first chip pad (not shown) facing downward.

The first through-electrode 20A may be composed of a conductive material. A first barrier metal 21A may be further disposed on a side surface of the first through-electrode 20A. The first barrier metal 21A may surround the side surface of the first through-electrode 20A. The first barrier metal 21A may include a metal compound such as titanium nitride (TiN) or tantalum nitride (TaN).

The first bonding pad 30A may be positioned on the upper surface of the first substrate 11A and may be connected to the other end of the first through-electrode 20A. The first bonding pad 30A may be disposed on the upper surface of the first substrate 11A around the other end of the first through-electrode 20A and on the other end of the first through-electrode 20A. The first bonding pad 30A may be electrically connected to the first integrated circuit 13A through the first through-electrode 20A and the first wiring layer 15A.

The first bonding pad 30A may include a metal material. The metal material may include aluminum (Al) and copper (Cu). Although not shown, a barrier metal surrounding the side and bottom surface of the first bonding pad 30A may be further provided.

A third insulating layer 18A may be disposed on the upper surface of the first substrate 11A. The third insulating layer 18A may surround the side surface of the first bonding pad 30A and expose the upper surface of the first bonding pad 30A.

The second semiconductor chip to the fourth semiconductor chip 10B, 10C, and 10D may be produced in the same process or the same manner as the first semiconductor chip 10A.

The second semiconductor chip 10B may be located on the first semiconductor chip 10A. Although not illustrated, an adhesive layer may be disposed under the second semiconductor chip 10B, and the second semiconductor chip 10B may be attached to the first semiconductor chip 10A via the adhesive layer. The second semiconductor chip 10B may be offset horizontally with respect to the first semiconductor chip 10A to expose the first bonding pad 30A. A third semiconductor chip 10C may be positioned on the second semiconductor chip 10B. Although not illustrated, an adhesive layer may be disposed under the third semiconductor chip 10C, and the third semiconductor chip 10C may be attached to the second semiconductor chip 10B via the adhesive layer. The third semiconductor chip 10C may be offset horizontally with respect to the second semiconductor chip 10B to expose the second bonding pad 30B of the second semiconductor chip 10B. A fourth semiconductor chip 10D may be positioned on the third semiconductor chip 10C. Although not shown, an adhesive layer may be disposed under the fourth semiconductor chip 10D, and the fourth semiconductor chip 10D can be attached to the third semiconductor chip 10C via the adhesive layer. The fourth semiconductor chip 10D may be offset horizontally with respect to the third semiconductor chip 10C so that a third bonding pad 30C of the third semiconductor chip 10C is exposed.

The first bonding wire 40A may be disposed on the first bonding pad 30A. The first bonding wire 40A may extend substantially in a vertical direction (VD) while one end is connected to the first bonding pad 30A. The first bonding wire 40A may include gold. The second bonding wire 40B may be disposed on the second bonding pad 30B of the second semiconductor chip 10B. A third bonding wire 40C may be disposed on the third bonding pad 30C of the third semiconductor chip 10C. A fourth bonding wire 40D may be disposed on the fourth bonding pad 30D of the fourth semiconductor chip 10D. The second bonding wire to the fourth bonding wire 40B, 40C, and 40D may have substantially the same structure as the first bonding wire 40A.

The first mold layer 50A may seal the first semiconductor chip to fourth semiconductor chip 10A, 10B, 10C, and 10D and the first bonding wire to fourth bonding wire 40A, 40B, 40C, and 40D. The first mold layer 50A may cover the first semiconductor chip to fourth semiconductor chip 10A, 10B, 10C, and 10D and surround the first bonding wire to fourth bonding wire 40A, 40B, 40C, and 40D. Upper sections of the first bonding wire to fourth bonding wire 40A, 40B, 40C, and 40D may be exposed to an upper surface of the first mold layer 50A. The first mold layer 50A may expose a lower surface of the first semiconductor chip 10A. The lower surface of the first mold layer 50A and the lower surface of the first semiconductor chip 10A may be on the same plane. Because the lower surface of the first semiconductor chip 10A is not covered with the first mold layer 50A, the heat generated during the operation of the first semiconductor chip to the fourth semiconductor chips 10A, 10B, 10C, and 10D can be released to the outside through the lower surface of the first semiconductor chip 10A without interference from the first mold layer 50A.

The first mold layer 50A may be formed by a molding process using a liquid sealant. The sealant may include an epoxy molding compound (EMC). The epoxy molding compound may include a resin and a filler.

The first redistribution layer 60A may be disposed on the first mold layer 50A and the first bonding wire to the fourth bonding wire 40A, 40B, 40C, and 40D. The first redistribution layer 60A may include first redistribution patterns 62A and first redistribution dielectric layers 61A.

The first redistribution patterns 62A may be connected to the first bonding wire to the fourth bonding wire 40A, 40B, 40C, and 40D. The first redistribution patterns 62A may be connected to the first semiconductor chip to the fourth semiconductor chip 10A, 10B, 10C, and 10D through the first bonding wire to the fourth bonding wire 40A, 40B, 40C, and 40D. The first redistribution patterns 62A may be insulated from each other by the first redistribution dielectric layers 61A.

The first connecting members 70A may be disposed on the first redistribution layer 60A. The first connecting members 70A may be connected to the first redistribution patterns 62A, and may be electrically connected to the first bonding wire to the fourth bonding wire 40A, 40B, 40C, and 40D through the first redistribution patterns 62A. The first connecting members 70A may include solder balls. Although FIG. 1 illustrates a case where the first redistribution patterns 62A included in the first redistribution layer 60A are arranged in two layers, the present disclosure is not limited thereto. The first redistribution patterns 62A included in the first redistribution layer 60A may be arranged in one or more layers.

The second semiconductor device 120 may be stacked on a first semiconductor device 110. The second semiconductor device 120 may have substantially the same structure as the first semiconductor device 110 described above. The second semiconductor device 120 may have a mirror-symmetrical structure with the first semiconductor device 110.

The second semiconductor device 120 may include a fifth semiconductor chip to an eighth semiconductor chip 10E, 10F, 10G, and 10H, a fifth bonding wire to an eighth bonding wire 40E, 40F, 40G, and 40H, a second mold layer 50B, a second redistribution layer 60B, and second connecting members 70B.

The second connecting member 70B of the second semiconductor device 120 may be bonded to the first connecting member 70A of the first semiconductor device 110. The second semiconductor device 120 may be disposed on the first semiconductor device 110 so that the second connecting members 70B on the first semiconductor device 110 face the first connecting members 70A of the first semiconductor device 110.

Any semiconductor chip included in the first semiconductor device 110 may be connected to another (for example, arbitrary, selected, etc.) semiconductor chip included in the first semiconductor device 110 through the first bonding wire to the fourth bonding wire 40A, 40B, 40C, and 40D and the first redistribution patterns 62A. Any semiconductor chip included in the second semiconductor device 120 may be connected to any other semiconductor chip included in the second semiconductor device 120 via the fifth bonding wire to the eighth bonding wire 40E, 40F, 40G, and 40H and the second redistribution patterns 62B. Any semiconductor chip included in the first semiconductor device 110 and any semiconductor chip included in the second semiconductor device may be electrically connected via the first redistribution patterns 62A, the first connecting members 70A, the second connecting members 70B, and the second redistribution patterns 62B.

At least one of through-electrodes included in the first semiconductor device 110 may be connected to at least one of other through-electrodes included in the first semiconductor device 110 via the first bonding wire to the fourth bonding wire 40A, 40B, 40C, and 40D and the first redistribution patterns 62A. At least one of the through-electrodes included in the second semiconductor device 120 may be connected to at least one of the other through-electrodes included in the second semiconductor device 120 via the fifth bonding wire to the eighth bonding wire 40E, 40F, 40G, and 40H and the second redistribution patterns 62B. At least one of the through-electrodes included in the first semiconductor device 110 and at least one of the through-electrodes included in the second semiconductor device 120 may be electrically connected via the first redistribution patterns 62A, the first connecting members 70A, the second connecting members 70B, and the second redistribution patterns 62B.

The first integrated circuit to the eighth integrated circuit 13A, 13B, 13C, 13D, 13E, 13F, 13G and 13H (where 13B to 13H correspond to 13A and are not individually labeled) included in the first semiconductor chip to the eighth semiconductor chip 10A, 10B, 10C, 10D, 10E, 10F, 10G and 10H each may include a first wiring pattern to an eighth wiring pattern 16A, 16B, 16C, 16D, 16E, 16F, 16G, and 16H (where 16B to 16H correspond to 16A and are not individually labeled), the first through-electrode to the eighth through-electrode 20A, 20B, 20C, 20D, 20E, 20F, 20G and 20H, and first bonding pad to the eighth bonding pad 30A, 30B, 30C, 30D, 30E, 30F. The first bonding wire to the eighth bonding wire 40A, 40B, 40C, 40D, 40E, 40F, 40G and 40H may be electrically connected to the first bonding wire to the eighth bonding wire 40A, 40B, 40C, 40D, 40E, 40F, 40G and 40H through the first through-electrode to the fourth through-electrode 20A, 20B, 20C, and 20D. The first bonding wire to fourth bonding wire 40A, 40B, 40C, and 40D, and the first redistribution patterns 62A. Any integrated circuit included in the first semiconductor device 110 may be connected to any other integrated circuit included in the first semiconductor device 110 through the first through-electrode to the fourth through-electrode 20A, 20B, 20C, and 20D, the first bonding wire to fourth bonding wire 40A, 40B, 40C, and 40D, and the first redistribution patterns 62A. Any integrated circuit included in the second semiconductor device 120 may be connected to another integrated circuit included in the second semiconductor device 120 through the fifth through-electrode to the eighth through-electrode 20E, 20F, 20G, and 20H, the fifth bonding wire to eighth bonding wire 40E, 40F, 40G, and 40H, and the second redistribution patterns 62B. Any integrated circuit included in the first semiconductor device 110 and any integrated circuit included in the second semiconductor device 120 may be electrically connected through at least one of the first through-electrode to the fourth through-electrode 20A, 20B, 20C, and 20D, the first redistribution patterns 62A, the first connecting members 70A, the second connecting members 70B, the second redistribution patterns 62B, and at least one of the fifth through-electrode to the eighth through-electrode 20E, 20F, 20G, and 20H.

The center mold layer 130 may fill and seal spaces between the first semiconductor device 110 and the second semiconductor device 120. The center mold layer 130 may have a molded underfill (MUF) shape that fills the spaces between the first semiconductor device 110 and the second semiconductor device 120. As another example, an adhesive layer may be provided between the first semiconductor device 110 and the second semiconductor device 120.

The center mold layer 130 may be formed by a molding process using a liquid sealant. The sealant may include an epoxy molding compound (EMC). The epoxy molding compound may include a resin and a filler.

In FIG. 1, the first semiconductor device 110 and the second semiconductor device 120 each include four semiconductor chips, but are not limited thereto. The number of semiconductor chips included in the first semiconductor device 110 or the second semiconductor device 120 may be 1 or more.

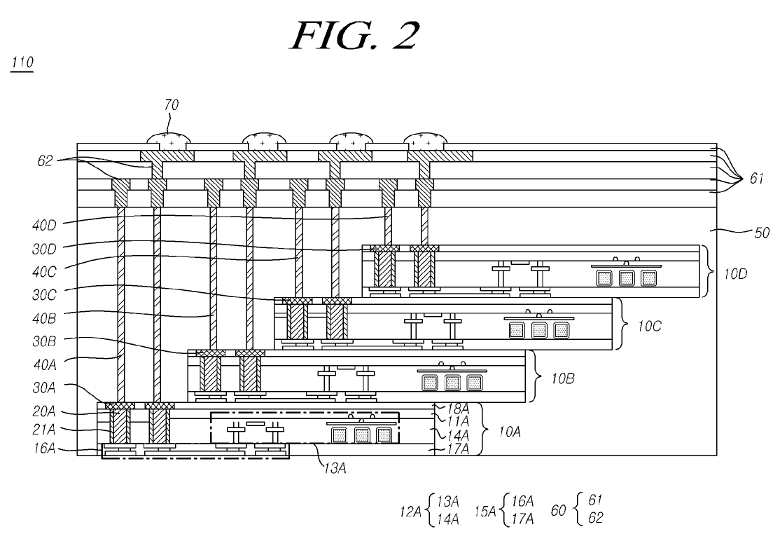

FIG. 2 is a cross-sectional view of a semiconductor device 110 according to an embodiment of the present disclosure.

The semiconductor device 110 according to an embodiment of the present disclosure may include a first semiconductor chip to a fourth semiconductor chip 10A, 10B, 10C, and 10D, a first bonding wire to a fourth bonding wire 40A, 40B, 40C, and 40D, a mold layer 50, a redistribution layer 60, and connecting members 70.

The first semiconductor chip 10A may include a first substrate 11A, a first circuit layer 12A, a first integrated circuit 13A, a first wiring layer 15A, a first through-electrode 20A, and a first bonding pad 30A. The second semiconductor chip to the fourth semiconductor chip 10B, 10C, and 10D may be produced in the same process or the same manner as the first semiconductor chip 10A.

The semiconductor device 110 may have substantially the same structure as the first semiconductor device 110 included in the semiconductor package 100 described above with reference to FIG. 1.

In FIG. 2, the semiconductor device 110 includes four semiconductor chips, but is not limited thereto. The number of semiconductor chips included in the semiconductor device 110 may be one or more.

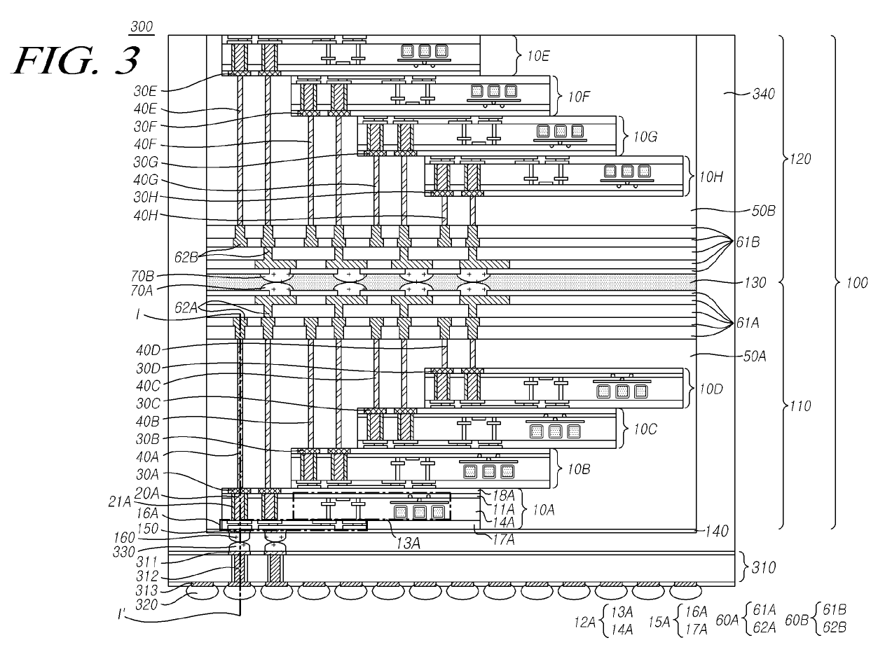

FIG. 3 is a cross-sectional view of a semiconductor package 300 according to another embodiment of the present disclosure.

Referring to FIG. 3, a semiconductor package 300 according to another embodiment of the present disclosure may include a first semiconductor device 110, a second semiconductor device 120, a base chip 310, and an outer mold layer 340. In addition, the semiconductor package 300 according to another embodiment of the present disclosure may further include a center mold layer 130, a third connecting member 160, a fourth connecting member 330, and an external connecting terminal 320.

The first semiconductor device 110, the second semiconductor device 120, and the center mold layer 130 may have substantially the same structure as those in the semiconductor package 100 described above with reference to FIG. 1. The first semiconductor device 110 may include a first semiconductor chip to a fourth semiconductor chip 10A, 10B, 10C, and 10D, a first bonding wire to a fourth bonding wire 40A, 40B, 40C, and 40D, a first mold layer 50A, a first redistribution layer 60A, and first connecting members 70A. The second semiconductor device 120 may include a fifth semiconductor chip to an eighth semiconductor chip 10E, 10F, 10G, and 10H, a fifth bonding wire to an eighth bonding wire 40E, 40F, 40G, and 40H, a second mold layer 50B, a second redistribution layer 60B, and second connecting members 70B.

The first semiconductor chip 10A may include a first substrate 11A, a first circuit layer 12A, a first integrated circuit 13A, a first wiring layer 15A, a first through-electrode 20A, and a first bonding pad 30A. The second semiconductor chip to the eighth semiconductor chip 10B, 10C, 10D, 10E, 10F, 10G, and 10H may be produced in the same process or the same manner as the first semiconductor chip 10A.

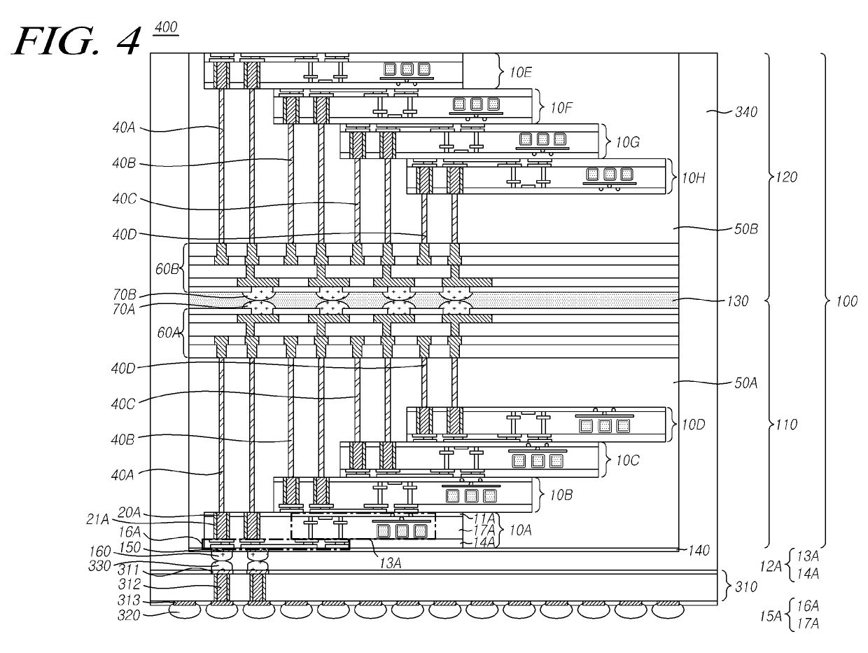

Referring to FIG. 4, in a semiconductor package 400 according to further another embodiment, the semiconductor chip may not include a bonding pad. In this case, the bonding wires may be respectively connected to the through-electrode.

Referring again to FIG. 3, a third connection pad 150 of the first semiconductor device 110 may be disposed under the first wiring layer 15A. The first through-electrode 20A may be disposed on the first wiring layer 15A. The third connection pad 150 may be electrically connected to the first through-electrode 20A and the first integrated circuit 13A through a first wiring pattern 16A included in the first wiring layer 15A. The third connection pad 150 may be electrically connected to the first redistribution layer 60A through the first through-electrode 20A. The third connection pad 150 may be connected to the second semiconductor chip to the fourth semiconductor chip 10B, 10C, and 10D through the first redistribution layer 60A.

A bottom insulating layer 140 may be disposed under a lower surface of a second insulating layer 17A included in the first semiconductor chip 10A and under a lower surface of the first molding layer 50A of the first semiconductor device 110. The bottom insulating layer 140 may expose the third connection pad 150.

The third connecting member 160 may be disposed under the third connection pad 150. The third connecting member 160 may be a solder layer or a laminated structure of a bump and a solder layer.

The base chip 310 may be provided with a fourth connection pad 311, a through-electrode 312, and an external connection pad 313. The fourth connection pad 311 may be disposed on an upper surface of the base chip 310. The through-electrode 312 may be connected to the fourth connection pad 311 and may extend vertically. The external connection pad 313 may be arranged on a lower surface of the base chip 310. Although not shown, the base chip 310 may include a base circuit, and the external connection pad 313 may be connected to the through-electrode 312 through the base circuit.

The fourth connecting member 330 may be disposed on the fourth connection pad 311, and an external connection terminal 320 may be disposed under the external connection pad 313. The fourth connecting member 330 may be a solder layer or a laminated structure of a bump and a solder layer. The external connection terminal 320 may include a solder ball.

The first semiconductor chip to the eighth semiconductor chip 10A, 10B, 10C, 10D, 10E, 10F, 10G, and 10H may be memory chips. The base chip 310 may be a logic chip for controlling the operation of the memory chip. In FIG. 3, each semiconductor device 110 and 120 includes four semiconductor chips, but is not limited thereto. The number of semiconductor chips included in the semiconductor device 110 or 120 according to one embodiment of the present disclosure may be one or more.

The first semiconductor device 110 may be stacked on the base chip 310, and the second semiconductor device 120 may be stacked on the first semiconductor device 110.

The first semiconductor device 110 may be stacked on the base chip 310 so that the third connecting member 160 overlaps with the fourth connecting member 330. The third connecting member 160 of the first semiconductor device 110 may be bonded on the fourth connecting member 330.

The second semiconductor device 120 may be stacked on the first semiconductor device 110 so that the second connecting member 70B overlaps with the first connecting member 70A. The second connecting member 70B may be bonded on the first connecting member 70A. The first semiconductor device 110 and the second semiconductor device 120 may be electrically connected through the first connecting member 70A and the second connecting member 70B.

The third connection pad 150 may be connected to the semiconductor chips 10E, 10F, 10G, and 10H of the second semiconductor device 120 through the first connecting member 70A and the second connecting member 70B.

The fourth connection pad 311 may be connected to the third connection pad 150 of the first semiconductor device 110 through the third connecting member 160 and the fourth connecting member 330. The fourth connection pad 311 may be electrically connected to any semiconductor chip included in the first semiconductor device 110 and the second semiconductor device 120 through the third connection pad 150.

The center mold layer 130 may fill and seal the spaces between the first semiconductor device 110 and the second semiconductor device 120. The center mold layer 130 included in the semiconductor package 300 according to another embodiment of the present invention may have substantially the same structure as the center mold layer 130 included in the semiconductor package 100 described above with reference to FIG. 1.

The outer mold layer 340 may be disposed on the base chip 310 and may seal the first semiconductor device 110 and the second semiconductor device 120.

The outer mold layer 340 may cover the side surfaces of the first semiconductor device 110 and the second semiconductor device 120. The outer mold layer 340 may expose an upper surface of the second semiconductor device 120. An upper surface of the outer mold layer 340 and the upper surface of the second semiconductor device 120 may be on the same plane. Because the upper surface of the second semiconductor device 120 is not covered by the outer mold layer 340, heat generated during operating the base chip 310 and the first semiconductor device 110 and the second semiconductor device 120 can be released to the outside through the upper surface of the second semiconductor device 120 without interference from the outer mold layer 340.

The outer mold layer 340 may be extended to fill the spaces between the base chip 310, the first semiconductor device 110, and the second semiconductor device 120. The outer mold layer 340 may have a molded underfill (MUF) shape that fills the spaces between the base chip 310, the first semiconductor device 110, and the second semiconductor device 120. As another example, the spaces between the base chip 310, the first semiconductor device 110, and the second semiconductor device 120 may be filled with an underfill material different from the outer mold layer 340. As another example, an adhesive layer may be disposed between the base chip 310 and the first semiconductor device 110, and between the first semiconductor device 110 and the second semiconductor device 120.

The outer mold layer 340 may be formed by a molding process using a liquid sealant. The sealant may include an epoxy molding compound (EMC). The epoxy molding compound may include a resin and a filler.

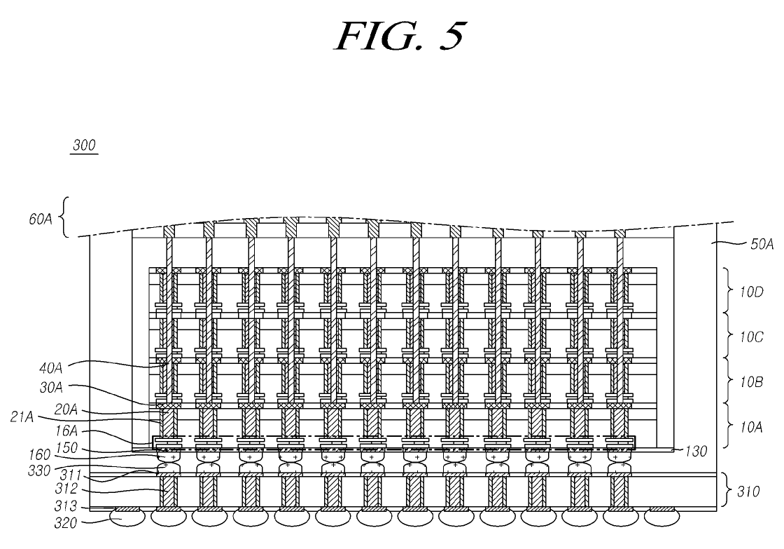

FIG. 5 is a cross-sectional view along line I-I` of the semiconductor package of FIG. 3.

Referring to FIG. 3 and FIG. 5, a bonding surface of the first semiconductor device 110 and the base chip 310 may be recognized as two bonding sections where the third connecting member 160 and the fourth connecting member 330 are bonded. When considering from a different angle, embodiments of the present disclosure may include multiple contact sections that are substantially formed on the bonding surface of the first semiconductor device 110 and the base chip 310. Accordingly, the embodiments may enable securing a stable and sufficient signal transmission path between the base chip 310 and the first semiconductor device 110.

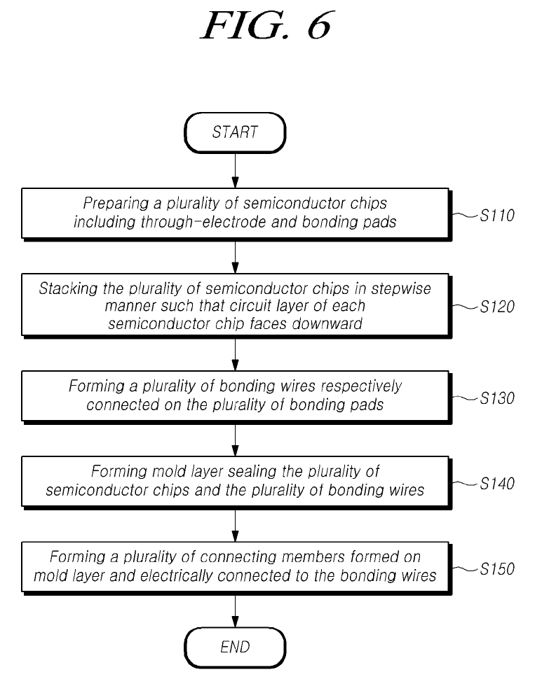

FIG. 6 is a flowchart for describing a method for manufacturing a semiconductor device according to an embodiment of the present disclosure.

Referring to FIG. 6, the method for manufacturing a semiconductor device (such as described herein above with respect to FIGS. 1-5 ) may include a step (S110) of preparing a plurality of semiconductor chips including a through-electrode and a bonding pad; a step (S120) of stacking the plurality of semiconductor chips in a stepwise manner so that the circuit layer of each semiconductor chip faces downward; a step (S130) of forming a plurality of bonding wires respectively connected on a plurality of bonding pads; a step (S140) of forming a mold layer sealing a plurality of semiconductor chips and a plurality of bonding wires; and a step (S150) of forming a plurality of connecting members formed on the mold layer and electrically connected to the bonding wires.

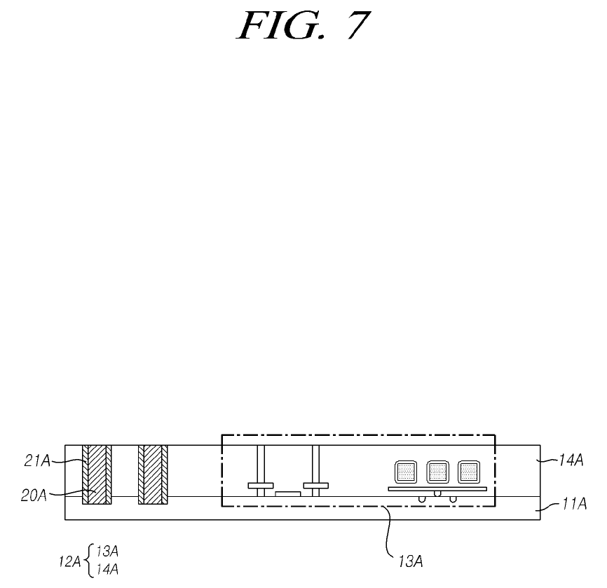

FIGS. 7-14 are cross-sectional views of a semiconductor device in a process sequence, according to an embodiment of the present disclosure.

Referring to FIG. 7, a first substrate 11A provided with a first circuit layer 12A and a first through-electrode 20A may be provided. The first circuit layer 12A may be configured on an upper surface side of the first substrate 11A. The first circuit layer 12A may include a first integrated circuit 13A and a first insulating layer 14A. The first integrated circuit 13A may include a memory cell. The first insulating layer 14A may be formed on an upper surface of the first substrate 11A and may cover the first integrated circuit 13A and the first through-electrode 20A.

The first through-electrode 20A may be disposed within a first semiconductor chip 10A. At least one first through-electrode 20A may be formed within the first semiconductor chip 10A. The first through-electrode 20A may vertically penetrate the first substrate 11A and the first circuit layer 12A. The first through-electrode 20A may be made of a conductive material. A first barrier metal 21A may be further disposed on a side of the first through-electrode 20A. The first barrier metal 21A may surround the side of the first through-electrode 20A.

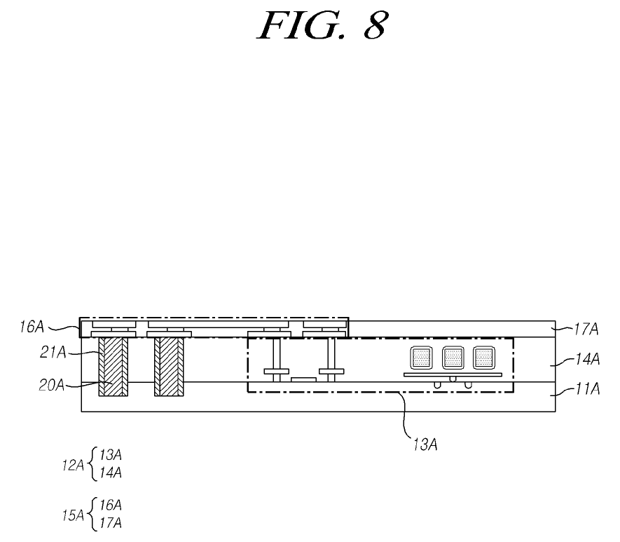

Referring to FIG. 8, first wiring patterns 16A and a second insulating layer 17A may be formed to form a first wiring layer 15A.

The first wiring layer 15A may be connected to the first through-electrode 20A and the first integrated circuit 13A.

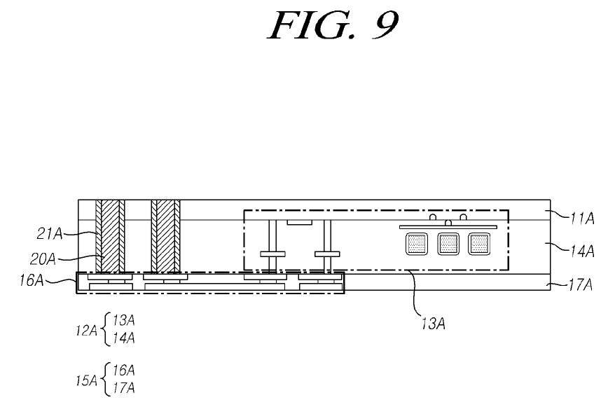

Referring to FIG. 9, the semiconductor chip may be rotated 180 degrees up and down so that the first substrate 11A faces the upper surface and the first wiring layer 15A faces the lower surface, and the upper section of the first through-electrode 20A may be exposed.

An upper section of the first through-electrode 20A may be exposed by polishing the first substrate 11A through a polishing process. The polishing process may include a chemical mechanical polishing (CMP) process.

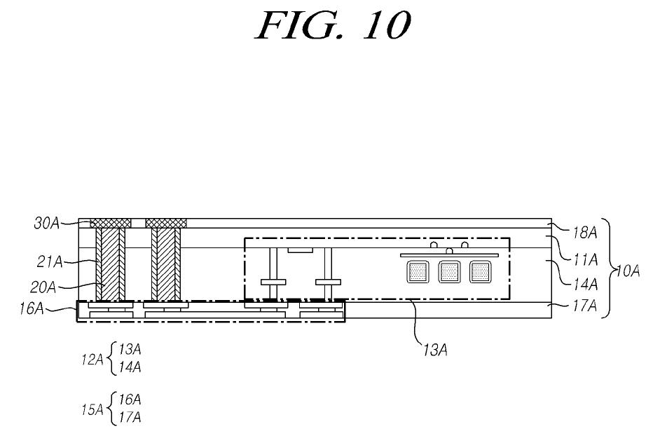

Referring to FIG. 10, a third insulating layer 18A and a first bonding pad 30A may be formed.

The third insulating layer 18A may be formed on an upper section of the first through-electrode 20A and the upper surface of the first substrate 11A. The third insulating layer 18A may include an oxide.

The first bonding pad 30A may be formed on the first through-electrode 20A. The first bonding pad 30A may be formed by exposing the first through-electrode 20A and the first substrate 11A around the first through-electrode 20A through a photo-etching process for the third insulating layer 18A, forming a conductive material to fill the etched third insulating layer 18A, and polishing the conductive material to expose the third insulating layer 18A. The conductive material may be produced by a plating process. The polishing process may include a chemical mechanical polishing (CMP) process. In this way, the first semiconductor chip 10A may be formed.

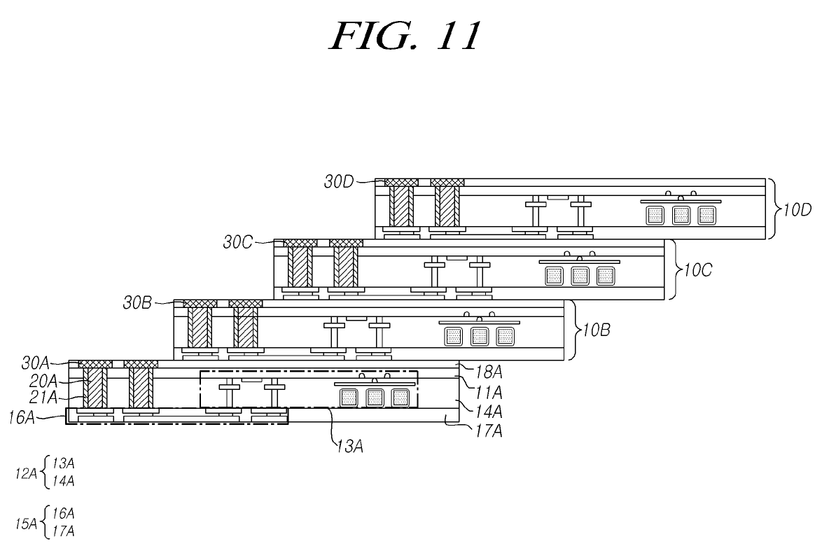

Referring to FIG. 11, the second semiconductor chip 10B, the third semiconductor chip 10C, and fourth semiconductor chip 10D may be stacked in a stepwise manner on the first semiconductor chip 10A. The second semiconductor chip 10B, the third semiconductor chip 10C, and fourth semiconductor chip 10D may be produced in the same process or the same manner as the first semiconductor chip 10A.

The second semiconductor chip 10B may be positioned on the first semiconductor chip 10A. The second semiconductor chip 10B may be offset horizontally with respect to the first semiconductor chip 10A to expose the first bonding pad 30A. The third semiconductor chip 10C may be positioned on the second semiconductor chip 10B. The third semiconductor chip 10C may be offset horizontally with respect to the second semiconductor chip 10B to expose the second bonding pad 30B. The fourth semiconductor chip 10D may be positioned on the third semiconductor chip 10C. The fourth semiconductor chip 10D may be offset horizontally with respect to the third semiconductor chip 10C to expose the third bonding pad 30C.

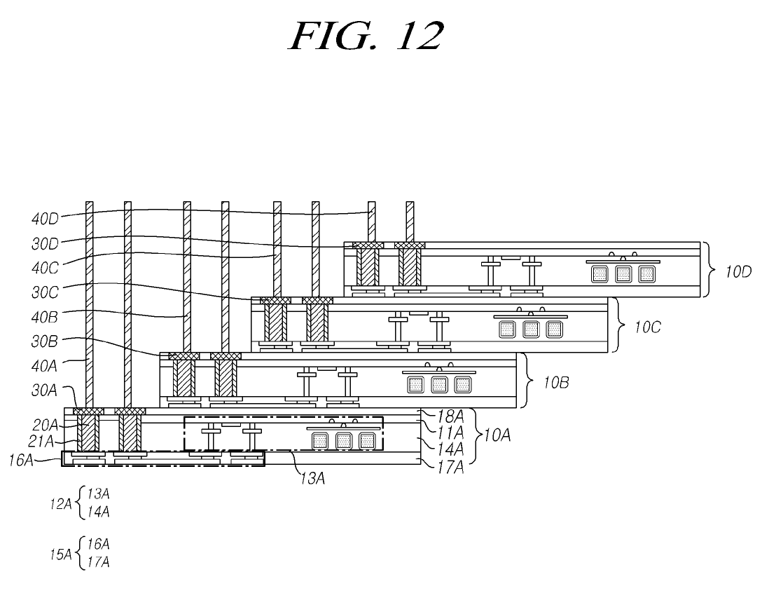

Referring to FIG. 12, a first bonding wire to a fourth bonding wire 40A, 40B, 40C, and 40D may be formed.

The first bonding wire to fourth bonding wire 40A, 40B, 40C, and 40D may be connected to a first bonding pad to a fourth bonding pad 30A, 30B, 30C, and 30D, respectively. The first bonding wire to fourth bonding wire 40A, 40B, 40C, and 40D may be formed of a conductive material. The conductive material may include gold (Au).

The first bonding wire to fourth bonding wire 40A, 40B, 40C, and 40D may be formed by a wire bonding process using a wire bonding device (not shown). Specifically, a bonding wire may be formed by forming a bonding ball at one end of a bonding wire using a capillary of a wire bonding device, bonding the formed bonding ball to a bonding pad, pulling the other end of the bonding wire in a vertical direction away from the bonding pad, for example, from below to above, to extend the other end of the wire to a desired position, and then cutting the other end of the wire.

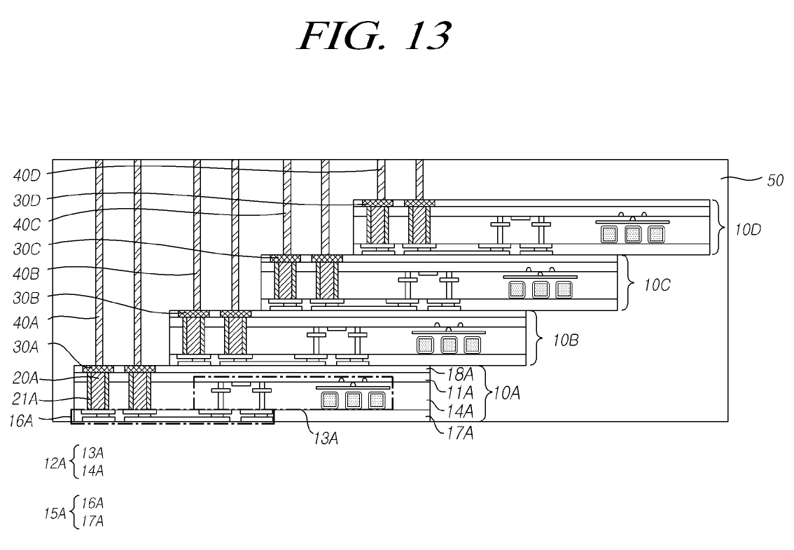

Referring to FIG. 13, the mold layer 50 may be formed to cover and seal the first semiconductor chip to the fourth semiconductor chip 10A, 10B, 10C, and 10D and the first bonding wire to the fourth bonding wire 40A, 40B, 40C, and 40D. The mold layer 50 may be formed by a molding process using a liquid sealant. The molding process may include mounting a sealant in which first semiconductor chip to the fourth semiconductor chip 10A, 10B, 10C, and 10D and the first bonding wire to the fourth bonding wire 40A, 40B, 40C, and 40D are disposed in a mold (not shown), introducing a liquid sealant into the mold, and curing the introduced sealant. The sealant may include an epoxy mold compound (EMC).

After the mold layer 50 is formed, the first bonding wire to the fourth bonding wire 40A, 40B, 40C, and 40D may be exposed to an upper surface of the mold layer 50 by a thinning process. The thinning process may include a chemical mechanical polishing (CMP) process or a grinding process.

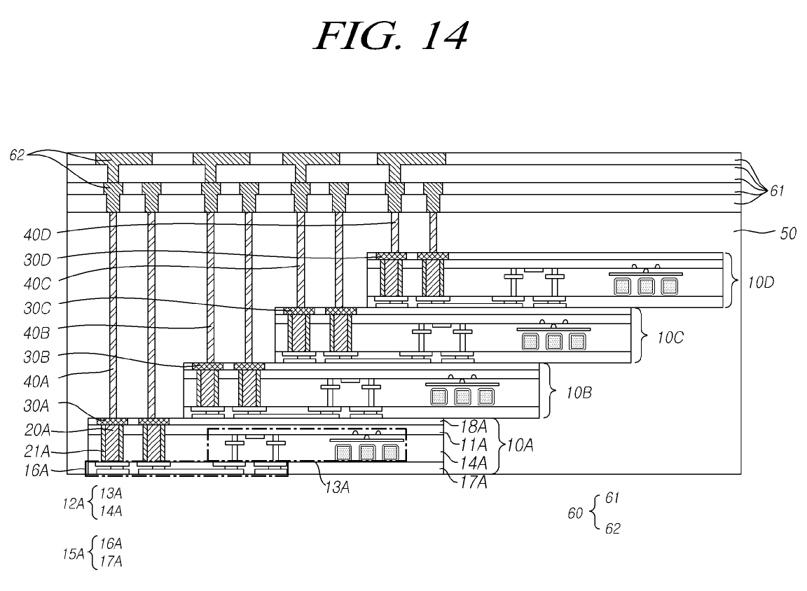

Referring to FIG. 14, a redistribution layer 60 including redistribution patterns 62 and redistribution dielectric layers 61 may be formed. The redistribution dielectric layers 61 may cover the upper sections of the first bonding wire to the fourth bonding wire 40A, 40B, 40C, and 40D and an upper surface of the molding layer 50. The redistribution dielectric layers 61 may include a nitride film or an oxide film.

The redistribution patterns 62 may formed by forming a trench exposing the redistribution dielectric layers 61 by a photolithography and etching process, and forming a conductive material within the trench. The conductive material may include aluminum or copper.

Referring back to FIG. 2, the connecting members 70 may be arranged on the redistribution patterns 62. The connecting members 70 may include solder balls.

In an embodiment described with reference to FIG. 6 to FIG. 14, the first redistribution patterns 62 included in the first redistribution layer 60 may be arranged in two layers, but is not limited thereto. The first redistribution patterns 62 included in the first redistribution layer 60 may be arranged in one or more layers.

According to embodiments of the present disclosure, a semiconductor chip included in a semiconductor device may include a through-electrode. The through-electrode may be connected to an integrated circuit through wiring patterns of a wiring layer. The semiconductor chip may be disposed in a face-down configuration with the chip pad facing downward. Because a bonding pad is formed directly on the through-electrode, the interface resistance may be reduced, which is advantageous for high-speed operation, and the overall chip thickness may be reduced by a stacked structure using the through-electrode instead of a bump.

According to embodiments of the present disclosure, by forming a through-electrode on a semiconductor chip and placing the semiconductor chip in a face-down configuration, the input/output connection structure may be placed on the back of the semiconductor chip, which may improve space efficiency. Because vertical connection is possible through the through-electrode, the signal transmission distance may be shortened and may be advantageous for high-speed signal processing.

According to embodiments of the present disclosure, the connecting members of first and second semiconductor devices may be bonded to each other to implement a device or package that electrically connects two semiconductor chips (or all chips when including a base chip).

In addition, heat dissipation is efficient, which facilitates heat management. In addition, heat generated inside the chip may be dispersed through the through-electrode, which may be advantageous to prevent overheating and maintain stable operation.

The above description is only an example of the technical idea of the present disclosure, and those with ordinary skill in the art to which the present disclosure pertains may make various modifications and variations without departing from the essential characteristics of the present disclosure. In addition, embodiments disclosed in the present disclosure are not intended to limit the technical idea of the present disclosure but to explain the technical idea of the present disclosure, and therefore the scope of the technical idea of the present disclosure is not limited by these embodiments.

What is claimed is:

1. A semiconductor package comprising:
a first semiconductor device; and
a second semiconductor device stacked on the first semiconductor device,
wherein the first semiconductor device includes:
a first semiconductor chip including a first substrate, a first circuit layer disposed under the first substrate, a first wiring layer disposed under the first circuit layer, a first through-electrode vertically penetrating the first substrate and the first circuit layer, and a first bonding pad disposed on the first substrate and connected to the first through-electrode;
a first bonding wire connected to the first bonding pad;
a first mold layer disposed to cover the first semiconductor chip and surround the first bonding wire;
a first redistribution layer disposed on the first mold layer and the first bonding wire; and
first connecting members disposed on the first redistribution layer, and
wherein the second semiconductor device includes:
a second semiconductor chip including a second substrate, a second circuit layer disposed on the second substrate, a second wiring layer disposed on the second circuit layer, a second through-electrode vertically penetrating the second substrate and the second circuit layer, and a second bonding pad disposed under the second substrate and connected to the second through-electrode;
a second bonding wire connected to the second bonding pad;
a second mold layer disposed to cover the second semiconductor chip and surround the second bonding wire;
a second redistribution layer disposed under the second mold layer and the second bonding wire; and
second connecting members disposed under the second redistribution layer and bonded to the first connecting members.

2. The semiconductor package of claim 1,
wherein the first semiconductor device further includes:
a third semiconductor chip disposed under the first semiconductor chip, the third semiconductor chip including a third substrate, a third circuit layer under the third substrate, a third wiring layer under the third circuit layer, a third through-electrode vertically penetrating the third substrate and the third circuit layer, and a third bonding pad disposed on the third substrate and connected to the third through-electrode; and
a third bonding wire connected to the third bonding pad,
wherein the second semiconductor device further includes:
a fourth semiconductor chip disposed on the second semiconductor chip, the fourth semiconductor chip including a fourth substrate, a fourth circuit layer on the fourth substrate, a fourth wiring layer on the fourth circuit layer, a fourth through-electrode vertically penetrating the fourth substrate and the fourth circuit layer, and a fourth bonding pad disposed under the fourth substrate and connected to the fourth through-electrode; and
a fourth bonding wire connected to the fourth bonding pad.

3. The semiconductor package of claim 2,
wherein the first semiconductor chip is horizontally offset with respect to the third semiconductor chip to not overlap with an area where the third bonding pad of the third semiconductor chip is disposed, and
wherein the second semiconductor chip is horizontally offset with respect to the fourth semiconductor chip to not overlap with an area where the fourth bonding pad of the fourth semiconductor chip is disposed.

4. The semiconductor package of claim 2,
wherein the first redistribution layer includes first redistribution patterns electrically connecting the first bonding wire and the first connecting members,
wherein the second redistribution layer includes second redistribution patterns electrically connecting the second bonding wire and the second connecting members, and
wherein at least one through-electrode included in the first semiconductor device is electrically connected to at least one through-electrode included in the second semiconductor device.

5. The semiconductor package of claim 1,
wherein the first circuit layer includes a first integrated circuit,
wherein the first wiring layer includes first wiring patterns connecting the first integrated circuit and the first through-electrode,
wherein the second circuit layer includes a second integrated circuit,
wherein the second wiring layer includes second wiring patterns connecting the second integrated circuit and the second through-electrode, and
wherein the first integrated circuit and the second integrated circuit are electrically connected.

6. The semiconductor package of claim 1,
wherein the first circuit layer includes an upper surface contacting the first substrate and a lower surface opposite to the upper surface,
wherein one end of the first through-electrode is disposed on the lower surface of the first circuit layer.

7. The semiconductor package of claim 1, further comprising a center mold layer disposed to seal the first redistribution layer, the second redistribution layer, the first connecting members, and the second connecting members.

8. A semiconductor device comprising:
a first semiconductor chip including a first substrate, a first circuit layer disposed under the first substrate, a first wiring layer disposed under the first circuit layer, a first through-electrode vertically penetrating the first substrate and the first circuit layer, and a first bonding pad disposed on the first substrate and connected to the first through-electrode;
a second semiconductor chip disposed on the first semiconductor chip, the second semiconductor chip including a second substrate, a second circuit layer disposed under the second substrate, a second wiring layer disposed under the second circuit layer, a second through-electrode vertically penetrating the second substrate and the second circuit layer, and a second bonding pad disposed on the second substrate and connected to the second through-electrode;
a first bonding wire connected to the first bonding pad;
a second bonding wire connected to the second bonding pad;
a mold layer disposed to cover the first semiconductor chip and the second semiconductor chip and surround the first bonding wire and the second bonding wire;
a redistribution layer disposed on the mold layer and the first bonding wire and the second bonding wire; and
connecting members disposed on the redistribution layer.

9. The semiconductor device of claim 8, wherein the second semiconductor chip is horizontally offset with respect to the first semiconductor chip to not overlap with an area where the first bonding pad of the first semiconductor chip is disposed.

10. The semiconductor device of claim 8,
wherein the redistribution layer includes redistribution patterns electrically connecting the first bonding wire and the connecting members, and
wherein the first through-electrode is electrically connected to the second through-electrode.

11. The semiconductor device of claim 8,
wherein the first circuit layer includes an upper surface contacting the first substrate and a lower surface opposite to the upper surface,
wherein one end of the first through-electrode is disposed on the lower surface of the first circuit layer.

12. The semiconductor device of claim 8,
wherein the first circuit layer includes a first integrated circuit,
wherein the first wiring layer includes first wiring patterns connecting the first integrated circuit and the first through-electrode,
wherein the second circuit layer includes a second integrated circuit,
wherein the second wiring layer includes second wiring patterns connecting the second integrated circuit and the second through-electrode, and
wherein the first integrated circuit and the second integrated circuit are electrically connected.

13. A semiconductor package comprising:
a base chip;
a first semiconductor device stacked on the base chip;
a second semiconductor device stacked on the first semiconductor device; and
an outer mold layer disposed on the base chip to seal the first semiconductor device and the second semiconductor device,
wherein the first semiconductor device includes:
a first semiconductor chip including a first substrate, a first circuit layer disposed under the first substrate, a first wiring layer disposed under the first circuit layer, and a first through-electrode vertically penetrating the first substrate and the first circuit layer;
a first bonding wire connected to the first through-electrode;
a first mold layer disposed to cover the first semiconductor chip and surround the first bonding wire;
a first redistribution layer disposed on the first mold layer and the first bonding wire; and
first connecting members disposed on the first redistribution layer,
wherein the second semiconductor device includes:
a second semiconductor chip including a second substrate, a second circuit layer disposed on the second substrate, a second wiring layer disposed on the second circuit layer, and a second through-electrode vertically penetrating the second substrate and the second circuit layer;
a second bonding wire connected to the second through-electrode;
a second mold layer covering the second semiconductor chip and surrounding the second bonding wire;
a second redistribution layer disposed under the second mold layer and the second bonding wire; and
second connecting members disposed under the second redistribution layer and bonded to the first connecting members, and
wherein third connecting members disposed under the first through-electrode and fourth connecting members disposed on the base chip are bonded to each other.

14. The semiconductor package of claim 13,
wherein the first semiconductor device further includes a first bonding pad disposed on an upper surface of the first substrate and connected to the first through-electrode and the first bonding wire, and
wherein the second semiconductor device further includes a second bonding pad disposed on a lower surface of the second substrate and connected to the second through-electrode and the second bonding wire.

15. The semiconductor package of claim 14,
wherein the first semiconductor device further includes:
a third semiconductor chip disposed under the first semiconductor chip, the third semiconductor chip including a third substrate, a third circuit layer under the third substrate, a first wiring layer under the first circuit layer, a third through-electrode vertically penetrating the third substrate and the third circuit layer, and a third bonding pad disposed on the third substrate and connected to the third through-electrode; and
a third bonding wire connected to the third through-electrode, and
wherein the second semiconductor device further includes:
a fourth semiconductor chip disposed on the second semiconductor chip, the fourth semiconductor chip including a fourth substrate, a fourth circuit layer on the fourth substrate, a fourth wiring layer on the fourth circuit layer, a fourth through-electrode vertically penetrating the fourth substrate and the fourth circuit layer, and a fourth bonding pad disposed under the fourth substrate and connected to the fourth through-electrode; and
a fourth bonding wire connected to the fourth through-electrode.

16. The semiconductor package of claim 15,
wherein the first semiconductor chip is horizontally offset with respect to the third semiconductor chip to not overlap with an area where the third bonding pad of the third semiconductor chip is disposed, and
wherein the second semiconductor chip is horizontally offset with respect to the fourth semiconductor chip to not overlap with an area where the fourth bonding pad of the fourth semiconductor chip is disposed.

17. The semiconductor package of claim 15,
wherein the first redistribution layer includes first redistribution patterns electrically connecting the first bonding wire and the first connecting members,
wherein the second redistribution layer includes second redistribution patterns electrically connecting the second bonding wire and the second connecting members, and
wherein at least one through-electrode included in the first semiconductor device is electrically connected to at least one through-electrode included in the second semiconductor device.
